(19) United States
(12) Patent Application Publication
(10) Pub. No.: US 2005/0067654 A1
(43) Pub. Date: Mar. 31, 2005

(54) Pressure-contactable power semiconductor module

(75) Inventors: Daniel Schneider, Zurich (CH); Dominik Trussel, Bremgarten (CH)

Correspondence Address: BURNS DOANE SWECKER & MATHIS L L P, POST OFFICE BOX 1404, ALEXANDRIA, VA, 22313-1404, US

(73) Assignee: ABB Schweiz AG, Baden (CH)

(21) Appl. No.: 10/488,477

(22) PCT Filed: Sep. 9, 2002
(86) PCT No.: PCT/CH02/00492

(30) Foreign Application Priority Data
Sep. 10, 2001 (EP) 01810870.4

(51) Int. Cl. H01L 29/76

(52) U.S. Cl. 257/341

(57) ABSTRACT

A power semiconductor module capable of pressure contact, with a base plate and a cover plate, is provided. The power semiconductor module comprises at least one semiconductor device with a first main terminal and with a second main terminal, which is in electrically conducting connection with the base plate, and also at least one spring element, which is arranged between the first main terminal and the cover plate. An electrically conducting connection between the first main terminal and the cover plate is led through an inner region of the spring element.

### TECHNICAL FIELD

The invention relates to the field of power electronics. It concerns a power semiconductor module capable of pressure contact according to the precharacterizing clause of the first claim.

### PRIOR ART

Such a power semiconductor module is already described in the laid-open patent application DE 199 03 245 A1. The power semiconductor module concerned is of the so-called pressure contact type with at least one semiconductor device, as shown in FIG. 1. A first main terminal 31 of the semiconductor device 3 is connected by at least one contact element 8 in an electrically conducting manner to a cover plate 2. With a second main terminal 32, the semiconductor device 3 is arranged on a base plate 1.

For reliable contacting in such power semiconductor modules, pressures of the order of magnitude of 1 kN/cm² are required. To generate these pressures while at the same time compensating for variations in the thickness of the semiconductor devices, in particular in the case of modules with a number of semiconductor devices, the contact element 8 has at least one spring element 4, which is generally formed as a spiral spring or as a stack of cup springs.

One difficulty is that of combining the spring element with a suitable current lead in the contact element. In DE 199 03 245 A1 this is solved by the current lead being led around the spring element by means of a flexible connecting clip or wire 81. For this reason, the connecting clip 81 must have a minimum length, which is determined by the dimensions of the spring element. In addition, the maximum cross section of such a connecting clip 81 is limited, since otherwise its mobility would be restricted. The two requirements just mentioned result in a lower limit for the thermal and electrical resistance of the connecting clip, which must be maintained, with respect to given dimensions of the spring element. For this reason, it must be ensured by selecting or designing the spring element that dimensions that permit tolerable resistance values of the connecting clip 81 are achieved.

In order to keep the semiconductor module itself, or else a possibly higher-level system, fully operational in the event of failure of one or more semiconductor devices 3, it is necessary in many cases for a defective semiconductor device 3 to switch over into a stable short-circuit mode (“short-circuit failure mode”, SCFM), in which a permanent, electrically conducting contact with lowest possible resistance and greatest possible current capacity exists between the first and second main terminals. If the SCFM occurs in the case of a semiconductor device in a pressure-contact power semiconductor module, a current through the module flows completely through the corresponding semiconductor device 3 and the connecting clip 81 of the associated contact element 8. Customary currents in this case lie in the range of a few kiloamperes. On account of the aforementioned thermal resistance of the connecting clip 81, temperatures far in excess of 200° C. can consequently occur in the semiconductor device 3. On the device side, the connecting clip 81 is heated up to similarly high temperatures as a result, which leads to severe stressing. The contact element in DE 199 03 245 A1 additionally has an internal pressure contact between the connecting clip 81 and a pressure stamp 9. As a result, the total number of pressure contacts in the power semiconductor module is increased, whereby overall electrical and thermal resistances are increased.

If a power semiconductor module comprises more than one contact element 8, it must be ensured when loading it with components that the connecting clips 81 do not touch one another. For this reason, correspondingly large distances must be provided between the contact elements 8 during production and/or correct mutual alignment of the contact elements 8 must be ensured during loading with components.

### SUMMARY OF THE INVENTION

The present invention is based on the object of providing a power semiconductor module of the type stated at the beginning which manages without a connecting clip led around a spring element of a contact element for the purpose of current leading. The invention is also based on the object of eliminating existing restrictions in the selection and design of a spring element with regard to its dimensions. The invention is further based on the object of minimizing the number of necessary pressure contacts in the power semiconductor module. Finally, the invention is based on the object of permitting a more compact construction of the power semiconductor modules and simplifying loading with components.

This object is achieved by a power semiconductor module according to claim 1. According to the invention, a combination comprising a current lead and a spring element is modified in such a way that an electrically conducting connection between a first main terminal of a semiconductor device and a cover plate is led through an inner region of the spring element. Current and heat are consequently no longer led around the spring element on the outside but are led within the spring element. In this way, both a minimum cross section and an average cross section of the conducting connection are increased in comparison with the prior art. Regions of the connection with cross-sectional values close to the minimum cross section are shortened. Altogether, a clear reduction in the electrical resistance, and in particular the thermal resistance, is achieved in this way. The inner region is understood hereafter as meaning a recess, opening, lead-through or the like that passes through the spring element substantially parallel to an intended direction of compression of the spring element.

Furthermore, the invention allows larger spring elements to be used. In addition, internal pressure contacts between component parts of the contact element can be eliminated. The elimination of the connecting clip allows a compact construction and simple loading with components of the power semiconductor modules according to the invention.

These and further objects, advantages and features of the invention are obvious from the more detailed description which follows of a preferred exemplary embodiment of the invention in conjunction with the drawings.

### BRIEF DESCRIPTION OF THE FIGURES

In the schematic drawings:

FIG. 1 shows a power semiconductor module according to the prior art,

FIG. 2a shows a section through part of a power semiconductor module according to the invention in a first embodiment, without the effect of a pressure contact force,

FIG. 2b shows the power semiconductor module from FIG. 2a, under the effect of a pressure contact force,

FIG. 3 shows a section through part of a preferred development of a power semiconductor module according to the invention and

FIG. 4 shows a section through part of a power semiconductor module according to the invention in a further preferred configuration.

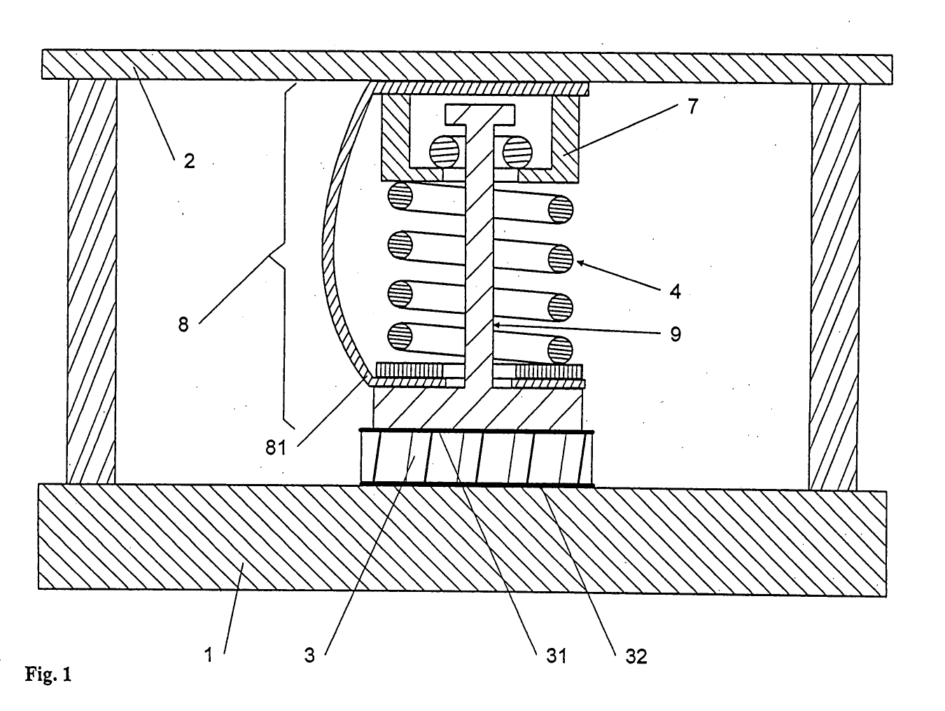

The reference numerals used in the drawing and their meaning are compiled in the list of designations. In principle, the same parts are provided with the same reference numerals.

### WAYS OF IMPLEMENTING THE INVENTION

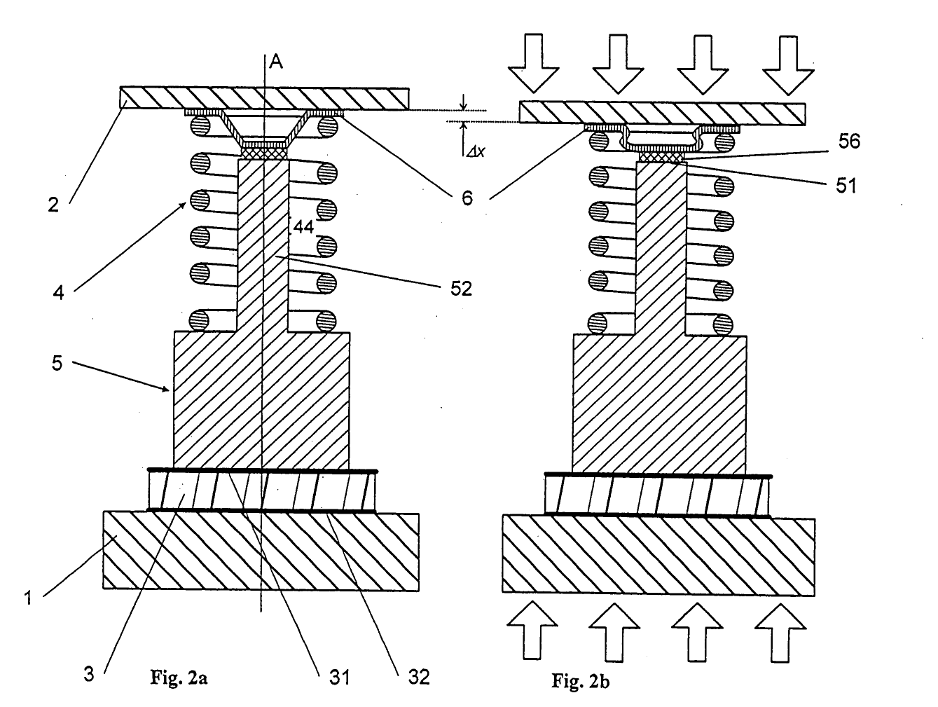

FIG. 2a schematically shows a section through part of a power semiconductor module according to the invention in a first embodiment, without the effect of a pressure contact -force. A semiconductor device 3 lies with a second main terminal 32 on a base plate 1. A contact stamp 5 lies with a contact area on a first main terminal 31 of the semiconductor device 3. A stamp neck 52 of the contact stamp 5 protrudes in this case into an inner region 44 of a spring element 4. In the case of this exemplary embodiment, the spring element 4 is a spiral spring. The inner region 44 is in this case a substantially cylindrical region, which is enclosed by turns of the spiral spring. On an end face 51 of the contact stamp 5 that is facing the cover plate 2, a deformable connecting element 6 is attached by means of a fixed, integral connection 56 and contacts a cover plate 2. The contact stamp 5 and the connecting element 6 form a current lead, the flexible part of which is laid locally over the spring assembly. By increasing the cross section of the contact stamp 5 at the end of the stamp neck 52 that is facing the base plate and a suitable form of the connecting element 6, the spring element 4 can transfer the force from the contact stamp 5 to the connecting element 6 and vice versa. In comparison with a connecting clip 81 used in the prior art, the connecting element 6 can be shortened, while at the same time increasing its cross section, which leads to a clear reduction both in the electrical resistance and in the thermal resistance. This also results in a better distribution of the thermal resistance between the contact stamp 5 and the connecting element 6. Consequently, a homogeneous temperature gradient is obtained when the power semiconductor module is in operation, a first temperature of the connecting element 6 remaining clearly below a second temperature of the semiconductor device 3. The fixed, integral connection 56 between the end face 51 and the connecting element 6 dispenses with the need for additional internal pressure contacts, which are present in the contact element according to the prior art. In the embodiment shown, the number of pressure contacts that are located between the cover plate 2 and the semiconductor device 3 can be reduced to two. The fixed, integral connection 56 is preferably a welded connection, but the connecting element 6 may also be attached to the end face 51 in some other manner. Likewise advantageous for example is a soldered connection or a low-temperature connection. It is also of advantage, however, if during production the connecting element 6 and the contact stamp 5 are already produced directly from one piece. Screwed or riveted connections can also be advantageously used. The contact stamp 5 and the connecting element 6 are preferably formed such that they are rotationally symmetrical with respect to an axis of rotation A, but other forms can also be used with advantage.

In the case where a number of power semiconductor modules are assembled to form a stack or a power semiconductor module is installed in a higher-level system, electrical contacting takes place via the base plate 1 and the cover plate 2, which for this purpose are subjected to pressure, whereby the power semiconductor module is compressed by a distance Ax, as shown in FIG. 2b. The force on the base plate 1 or cover plate 2 is transferred by the spring element 4 to the connecting element 6 or the contact stamp 5. Preferably, there are lateral module walls (not shown in the figure) that determine a maximum compressibility Axon of the power semiconductor module. If a linear spring with a spring constant k is used, the force F on the connecting element 6 and the contact stamp 5 in a completely compressed state of the power semiconductor module is given by F=kΔxₘₐₓ. Nonlinear springs can also be advantageously used.

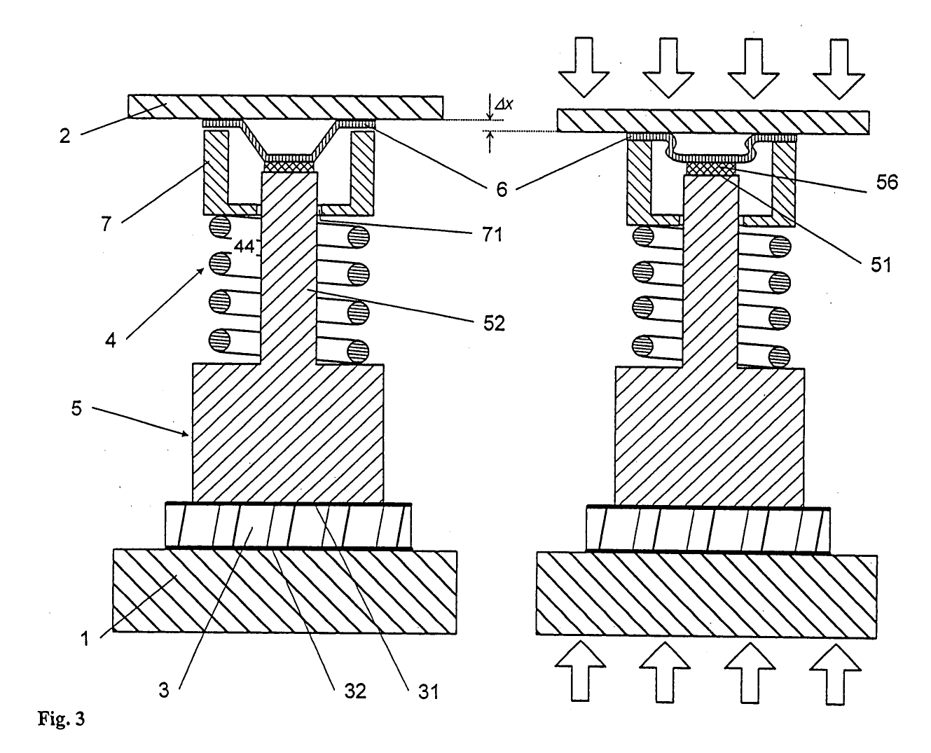

FIG. 3 schematically shows a section through part of a preferred development of a power semiconductor module according to the invention. In the case of this embodiment, a pressure-exerting element 7 is present between the spring element 4 and the connecting element 6. The pressure-exerting element 7 has in this case a cup form and preferably consists of insulating material. The stamp neck 52 of the contact stamp 5 is led through an opening 71 in a bottom wall of the pressure-exerting element 7. A pressure-exerting element 7 of a suitable form permits a uniform distribution of the force transferred to the connecting element 6, independently of the type and form of the spring element 4. Furthermore, the pressure-exerting element 7 can be advantageously used for increasing the usable spring excursion.

In a preferred configuration of the invention, the spring element 4 is formed by a stack of cup springs, the individual cup springs respectively having at least one bore or hole and being assembled to form a spring element in such a way that the bores or holes produce an inner region suitable for leading through an electrically conducting connection. In the case of such a spring element, properties such as, for example, a length in the relaxed state or else a spring characteristic can be influenced by the type and/or number of cup springs used in the stack. This permits increased flexibility in the production of the power semiconductor modules according to the invention, because a wide range of power semiconductor modules with different pressure contact behavior can be produced with a small number of different cup springs. The use of a stack of a number of cup springs also has the effect of reducing deviations from a desired behavior of the spring element caused by production tolerances. In comparison with the prior art, elimination of the outer connecting clip 81 provides more space for larger cup springs. This has the consequence that firstly the diameter of the inner region can be greatly increased, which allows an increased current-leading cross section within the springs, and secondly the larger cup springs can be bent to a greater extent, with internal stresses remaining small. Consequently, fewer springs are required to achieve a desired spring characteristic.

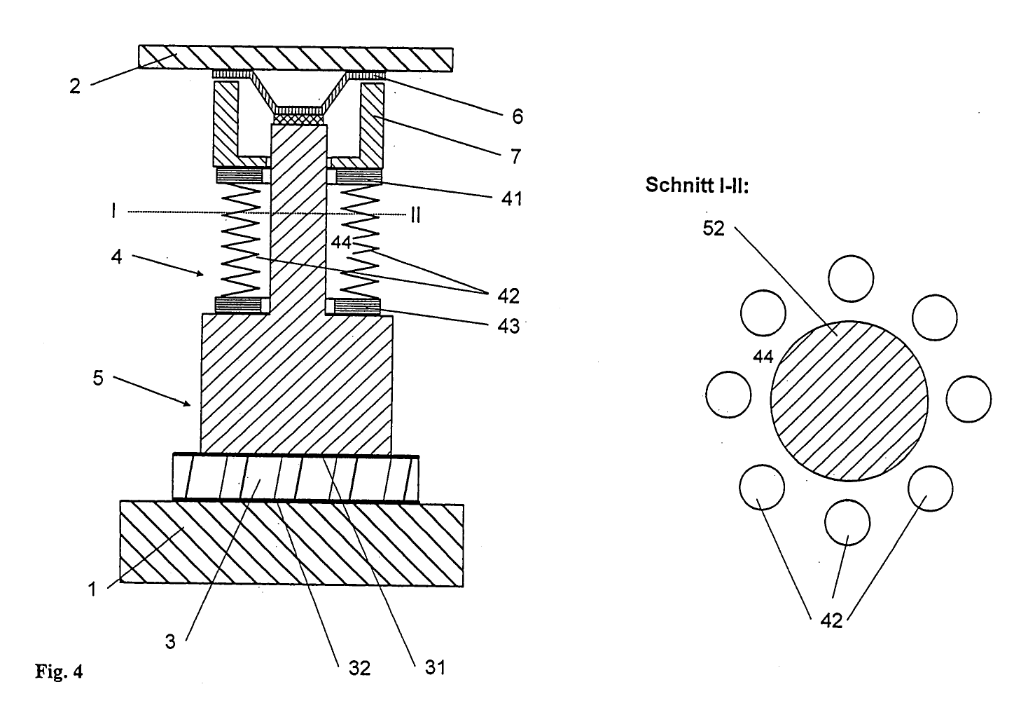

In a further preferred configuration of the invention, the spring element 4 is assembled from individual springs 42 that are arranged in parallel and the first ends of which are mounted on a first fastening ring 41 and the second ends of which are mounted on a second fastening 43, as can be seen in FIG. 4. A region between the individual springs 42 forms the inner region 44 of the spring element. Here, too, properties of the spring element 4 can be influenced by changing the type and/or number of the individual springs 42 used in the spring element 4. Instead of the first fastening ring 41, there may advantageously be means for fastening the individual springs 42 directly on the pressure-exerting element 7. Similarly, instead of the second fastening ring 43, there may be means for fastening the individual springs 42 on the contact stamp 5.

In a preferred configuration of the invention, the semiconductor device 3 is an individual semiconductor chip, a first and a second main electrode respectively forming the first and second main terminals.

In a further preferred configuration of the invention, the semiconductor device 3 is a submodule which comprises a number of semiconductor chips connected in parallel and/or in series and in which the individual semiconductor chips are interconnected in a suitable way with one another and with the first and second main terminals.

In a further preferred configuration of the invention, the power semiconductor module has between the first main electrode 31 and the contact stamp 5 and/or between the second main electrode 32 and the base plate 1 intermediate layers in the form of a foil, plate and/or solder layer. Presented as an example of such an intermediate layer are plates that are adapted in their thermal expansion to the semiconductor device 3 and are produced for example from Mo, Cu, or Mo—Cu, Al—C, Cu—C or Al—Si—C composites.

List of Designations
1 Base plate
2 Cover plate
3 Semiconductor device
31 First main terminal
32 Second main terminal
4 Spring element
41 First fastening ring
42 Individual springs
43 Second fastening ring
44 Inner region
5 Contact stamp
51 End face of the contact stamp
52 Stamp neck
56 Fixed, integral connection
6 Connecting element
7 Pressure-exerting element
71 Opening
8 Contact element
81 Connecting clip or wire
9 Pressure stamp

1. A power semiconductor module capable of pressure contact, comprising
a base plate,
a cover plate,
at least one semiconductor device with a first main terminal and with a second main terminal, which is in electrically conducting connection with the base plate,
at least one spring element, which is arranged between the first main terminal and the cover plate,
wherein
an electrically conducting connection comprising a contact stamp between the first main terminal and the cover plate is led through an inner region of the spring element, the spring element serving for the force transfer to the cover plate and to the contact stamp.

2. The power semiconductor module as claimed in claim wherein
the contact stamp has on an end face facing the cover plate a deformable connecting element, which is in electrically conducting connection with the cover plate.

3. The power semiconductor module as claimed in claim wherein
the connecting element is attached on the end face of the contact stamp by means of a fixed, integral connection.

4. The power semiconductor module as claimed-in claim wherein
a force can be transferred between the contact stamp and the connecting element by the spring element.

5. The power semiconductor module as claimed in claim wherein
for transferring the force between the contact stamp and the connecting element, a pressure-exerting element is provided between the contact stamp and the connecting element.

6. The power semiconductor module as claimed in claim wherein
the pressure-exerting element is formed substantially as a cup and a stamp neck of the contact stamp is led through an opening in the bottom of the pressure-exerting element.

7. The power semiconductor module as claimed in claim 1, wherein
the pressure-exerting element consists of electrically insulating material.

8. The power semiconductor module as claimed in one claim 1, wherein
the spring element is formed by a stack of cup springs.

9. The power semiconductor module as claimed in claim 1, wherein
the spring element has a number of individual springs arranged in parallel.

10. The power semiconductor module as claimed in claim 1, wherein
between the first main electrode and the contact stamp there is at least one electrically conducting layer.

11. The power semiconductor module as claimed in claim 1, wherein
between the second main electrode and the base plate there is at least one electrically conducting layer.
